(19) United States
(12) Patent Application Publication
(10) Pub. No.: US 2014/0145139 A1
(43) Pub. Date: May 29, 2014

(54) TRANSPARENT FLEXIBLE RESISTIVE MEMORY AND FABRICATION METHOD THEREOF

(71) Applicants: Ru Huang, Beijing (CN); Yu Tang, Beijing (CN); Yimao Cai, Beijing (CN); Lijie Zhang, Beijing (CN); Gengyu Yang, Beijing (CN); Shenghu Tan, Beijing (CN); Yue Pan, Beijing (CN); Poren Tang, Beijing (CN)

(72) Inventors: Ru Huang, Beijing (CN); Yu Tang, Beijing (CN); Yimao Cai, Beijing (CN); Lijie Zhang, Beijing (CN); Gengyu Yang, Beijing (CN); Shenghu Tan, Beijing (CN); Yue Pan, Beijing (CN); Poren Tang, Beijing (CN)

(21) Appl. No.: 13/581,470

(22) PCT Filed: Feb. 22, 2012
(86) PCT No.: PCT/CN12/71426

§ 371 Date: Aug. 28, 2012

(30) Foreign Application Priority Data
Jul. 13, 2011 (CN) 201110195121.2

(51) Int. Cl. H01L 45/00

(52) U.S. Cl. CPC H01L 45/149; H01L 45/1675
USPC 257/4; 438/99

(57) ABSTRACT

The present invention discloses a transparent flexible resistive memory and a fabrication method thereof. The transparent flexible resistive memory includes a transparent flexible substrate, a memory unit with a MIM capacitor structure over the substrate, wherein a bottom electrode and a top electrode of the memory unit are transparent and flexible, and an intermediate resistive layer is a transparent flexible film of poly(p-xylylene). Poly(p-xylylene) has excellent resistive characteristics. In the device, the substrate, the electrodes and the intermediate resistive layer are all formed of transparent flexible material so that a completely transparent flexible resistive memory which can be used in a transparent flexible electronic system is obtained.

### CROSS REFERENCE OF RELATED APPLICATION

The present application claims priority of Chinese Patent Application No. 201110195121.2, filed in State Intellectual Property Office of China on Jul. 13, 2011, which is incorporated herein by reference in its entirety.

### FIELD OF THE INVENTION

The present invention belongs to flexible electronics and relates to fields of electronic display, polymer and CMOS mixing integrated circuit, in particular to a transparent flexible organic resistive random access memory and a fabrication method thereof.

### BACKGROUND OF THE INVENTION

Recently, integrated circuits (IC) are developing more and more rapidly and have more and more application. Electronic systems are being combined with other systems so as to perform more powerful functions. Under such a development tendency, a special IC system, i.e. a flexible electronic system, emerges as required. The flexible electronic system may be flexible or stretchable, thus may cover curved surfaces or mobile components. The application range of the flexible electronic system is extended greatly, for example, transparent electronic devices can be widely used in the field of transparent display. Transparent cellphone and some other transparent products have been made successfully.

On the other hand, resistive memory plays an important role in integrated circuits, and the research thereon also develops rapidly. The resistive memory falls into the category of nonvolatile memory. Nonvolatile memories in current market are mainly flash memories. With development of integrated circuit technology, novel memory with higher storage capacity, higher response speed and lower cost is required to meet the new demands. A new generation of memory technology represented by resistive memory has become a research focus. The resistive memory is a memory with a new concept. The basic principle of the resistive memory lies in that, the resistance of material may be reversibly switched between a high resistance state (“0” state) and a low resistance state (“1” state) under a stimulation of an externally applied voltage or current, thus a function of storing data (storing “0” or “1”) is achieved. Compared with conventional flash memory, the resistive memory has great advantages including simple structure and simple fabricating process, high speed, low operation voltage, etc.

In recent years, flexible resistive memory fabricated on a plastic or rubber substrate and resistive memory fabricated on a transparent glass substrate have been reported. However, the electrode film (most of which are metals) and the resistive layer of the resistive memory device are usually not completely transparent, thus it is difficult to get completely transparent devices. In other word, there is not a transparent flexible resistive memory that can have transparent flexible electrode, resistive layer and substrate. Transparent flexible resistive memory not only has the advantages of transparent and flexible, but also has the characteristics of the resistive memory. It can be used in e-paper, electronic display (e.g. display screen) and other related transparent electronic products.

### SUMMARY OF THE INVENTION

An objective of an embodiment of the present invention is to provide a completely transparent resistive memory and a fabrication method thereof.

A technical solution of an embodiment of the present invention is as follow.

A transparent flexible resistive memory includes a transparent flexible substrate, a memory unit with a MIM (metal insulator metal) capacitor structure on the substrate, wherein a bottom electrode and a top electrode of the memory unit are transparent and an intermediate resistive layer is a transparent flexible film of poly(p-xylylene).

In the transparent flexible resistive memory mentioned above, the substrate may be a film formed of poly(p-xylylene) or other transparent flexible materials, including plastic and rubber material, such as PDMS (polydimethylsiloxane) film, PET (polyethylene terephthalate) film and PEN (poly(ethylene naphthalate)) film; the transparent flexible electrodes may be transparent ITO (indium tin oxide) film or other transparent electrodes, such as ZnO film, graphene film, polymeric materials including PEDOT (poly(3,4-ethylenedioxythiophene)), and so on. The poly(p-xylylene) may be poly(p-xylylene)-C, poly(p-xylylene)-N or poly(p-xylylene)-D.

The thickness of the above mentioned substrate is in a range of 2-500 μm; the thickness of the intermediate resistive layer, i.e. poly(p-xylylene) film, is in an range of 30-50 nm; the thickness of the top electrode is in a range of 100-500 nm; the thickness of the bottom electrode is in a range of 100-500 nm.

An embodiment of the present invention also provides a fabrication method of the above mentioned transparent flexible memory, and the method includes the steps of:

depositing a transparent flexible material over a base plate to form a transparent flexible substrate;

forming a transparent flexible bottom electrode over the substrate;

depositing a polymer film of poly(p-xylylene) over the bottom electrode as an intermediate resistive layer;

forming a transparent flexible top electrode over the intermediate resistive layer;

peeling the transparent flexible film substrate from the base plate to obtain the transparent flexible resistive memory.

In the above step 1), the base plate is generally a silicon wafer or a glass wafer; the transparent flexible material is preferably poly(p-xylylene), which is deposited as the substrate over the base plate by using a polymer chemical vapor deposition (polymer CVD) method with a deposition speed between 20 nm/min and 200 nm/min in a vacuum atmosphere.

In the above step 2), an ITO film is preferably sputtered over the substrate, and then a photolithography process is performed to define the bottom electrode.

In the above step 3), the polymer film of poly(p-xylylene) is deposited by employing a polymer CVD method with a deposition speed between 1 nm/min and 10 nm/min in a vacuum atmosphere.

In the above step 4), an ITO film is preferably sputtered on the intermediate resistive layer, and then a photolithography process is performed to define the top electrode.

Further, after the step 3) and before the step 4, lead-out vias of the bottom electrode is defined by performing a photolithography process and a reactive ion etching process to the polymer film of poly(p-xylylene). In the step 4, the lead-out vias are filled with material of the top electrode to lead the bottom electrode out.

Compared with the prior art, beneficial effects of embodiments of the present invention are as follow.

The poly(p-xylylene) material employed in the intermediate resistive layer of the resistive memory of the embodiments of the present invention has excellent resistive characteristics (the resistive characteristic curve is shown in FIG. 1). Moreover, the substrate, the electrodes and the intermediate resistive layer are all formed of transparent flexible materials, and thus the resistive memory is a completely transparent flexible resistive memory. It can be used in a transparent flexible electronic system.

### BRIEF DESCRIPTION OF THE DRAWINGS

FIG. 1 is resistive characteristic I-V curve of poly(p-xylylene).

FIG. 2 is a schematic diagram illustrating a MIM capacitor structure of a transparent flexible resistive memory of an embodiment of the present invention.

FIGS. 3(a) to 3(f) are schematic diagrams illustrating processes of steps for fabricating the transparent flexible resistive memory of embodiment 2.

### DETAILED DESCRIPTION OF THE EMBODIMENTS

Embodiments of the present invention are described in more detail below with reference to the accompany drawings and detailed embodiments.

### Embodiment 1

### The Resistive Characteristic I-V Curves of Poly(p-xylylene) Based Device

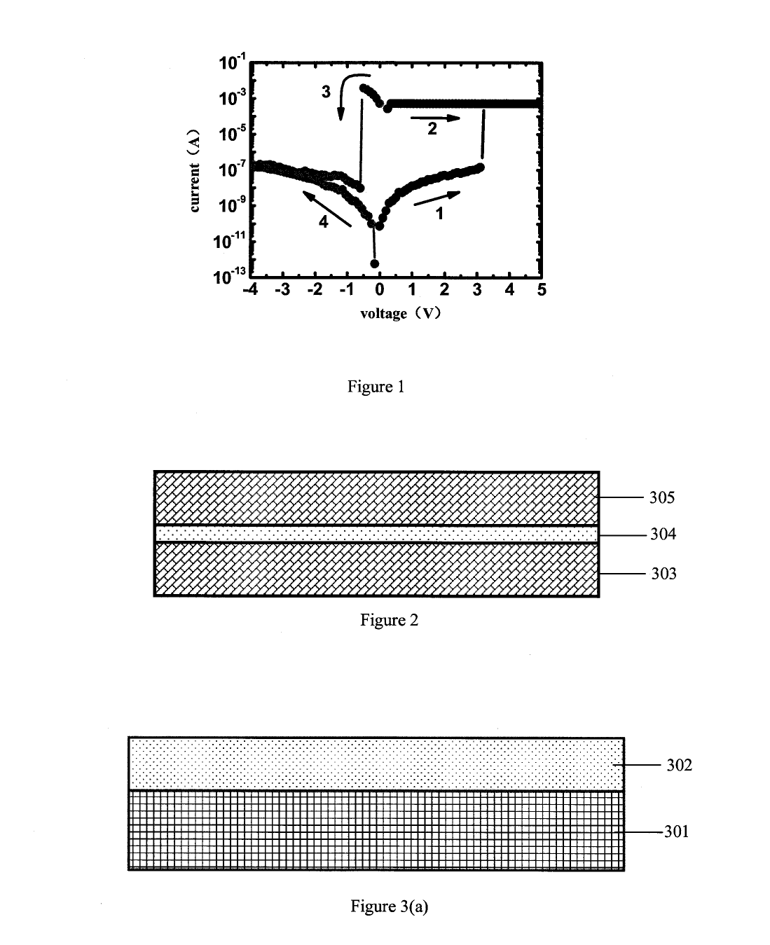

FIG. 1 is an I-V characteristic curve of a device with a MIM capacitor structure in which an intermediate resistive layer is formed of poly(p-xylylene)-C (Parylene-C), the top electrode is formed of Al, and the bottom electrode is formed of W, wherein reference sign 1 denotes a process that the device changes from the high resistance state to the low resistance state under a stimulation of a positive voltage; reference sign 2 denotes a process that the low resistance state is maintained; reference sign 3 denotes a process that the device changes from the low resistance state to the high resistance state under a stimulation of a negative voltage; reference sign 4 denotes a process that the high resistance state is maintained. The bottom electrode of the device is grounded, thus the voltage applied to the top electrode may control the resistance of the memory so as to allow the switching between the high resistance state and the low resistance state, i.e. the switching between the two states “0” and “1” of the memory. The resistance ratio of the high resistance state and the low resistance state under a low read voltage (such as 0.1V) is up to 10⁸, representing a high discrimination between the states “0” and “1”. It can be seen that the poly(p-xylylene) material has excellent resistive characteristics.

### Embodiment 2

### Fabrication of Transparent Flexible Resistive Memory

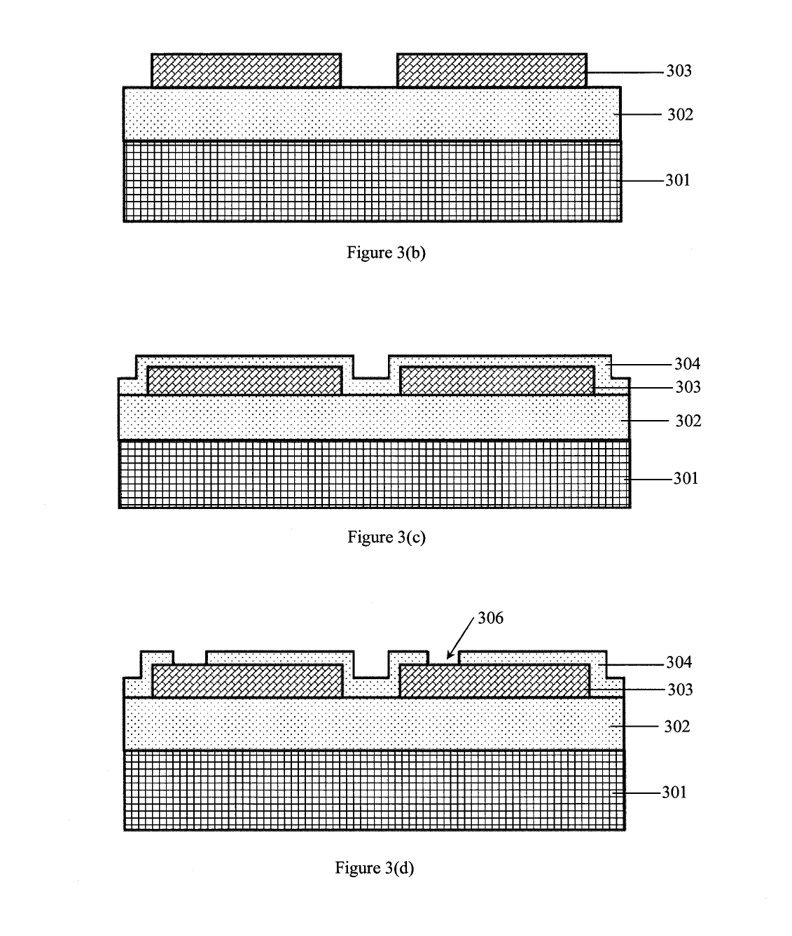

FIG. 2 shows a MIM capacitor structure of the transparent flexible resistive memory of the embodiment of the present invention, which includes a bottom electrode 303, an intermediate resistive layer 304 and a top electrode 305. The fabrication process of the resistive memory is as follow.

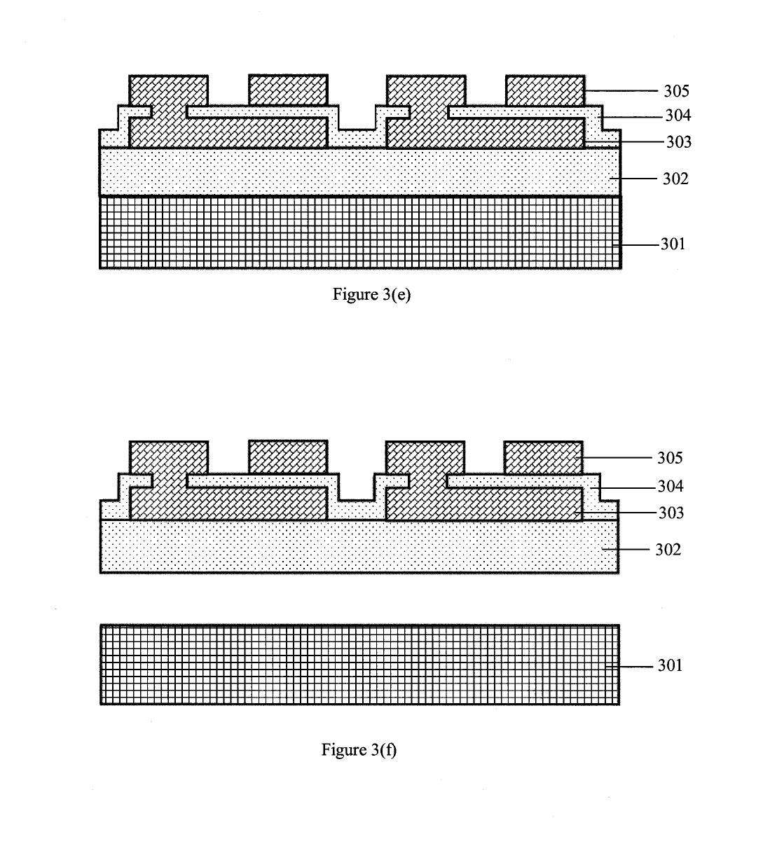

A thick film 302 of poly(p-xylylene)-C (Parylene-C) is deposited over a silicon wafer or glass wafer 301 by using polymer CVD technology, and the film 302 has a thickness of 2 μm to 500 μm, as shown in FIG. 3(a).

ITO is used for the bottom electrode 303 by PVD method or other film-forming method in IC process, with a thickness of 200 nm to 500 nm, and the bottom electrode is patterned by using the photolithography process, as shown in FIG. 3(b) (two identical memory units formed on the same substrate are shown in the figure).

A thin film 304 of poly(p-xylylene) type C (Parylene-C) is deposited through polymer CVD technology in which the film thickness is in a range of 30-50 nm and the deposition speed is between 1 nm/min and 10 nm/min.

Lead-out vias 306 of the bottom electrode is defined through a photolithography process and an RIE etching process, as shown in FIG. 3(d).

ITO is sputtered via a PVD process, with a thickness of 200 nm to 500 nm, and the top electrode 305 is defined through a photolithographic process and a lift-off process while the bottom electrode is led out, as shown in FIG. 3(e).

The flexible substrate is separated from the base sheet, as shown in FIG. 3(f), so as to obtain the transparent flexible resistive memory.

A transparent flexible resistive memory can be obtained by using a flexible transparent poly(p-xylylene) film as the flexible substrate and the intermediate resistive layer of the resistive memory and using a transparent ITO film as the top electrode and the bottom electrode. The transparent flexible resistive memory can be widely applied in transparent electronic products.

While the material and structure of the resistive memory of the present invention and the fabrication method thereof have been described in detail with respect to specific embodiments in the description, it should be understood by those skilled in the art that implementations of the present invention are not limited to the scope described in the embodiments, and various modifications and substitutions may be made to the present invention without departing from the spirit and scope of the present invention. For example, the poly(p-xylylene)-C (Parylene-C) material of the intermediate resistive layer and the substrate may be substituted by poly(p-xylylene)-N (Parylene-N) or poly(p-xylylene)-D (Parylene-D). The fabrication method also is not limited to the content disclosed in the embodiments.

1. A resistive memory comprising a transparent flexible substrate, a memory unit with a MIM capacitor structure over the substrate, wherein a bottom electrode and a top electrode of the memory unit are transparent and flexible, and an intermediate resistive layer is a transparent film of poly(p-xylylene).

2. The resistive memory according to claim 1, wherein, the substrate is a poly(p-xylylene) film, a polydimethylsiloxane film, a polyethylene terephthalate film or a poly(ethylene naphthalate) film.

3. The resistive memory according to claim 1, wherein, materials of the transparent flexible electrodes are indium tin oxide, ZnO, graphene or poly(3,4-ethylenedioxythiophene).

4. The resistive memory according to claim 1, wherein, the poly(p-xylylene) is a polymer of poly(p-xylylene)-C, poly(p-xylylene)-N or poly(p-xylylene)-D.

5. The resistive memory according to claim 1, wherein, the thickness of the substrate is in a range of 2-500 μm, the thicknesses of the bottom electrode and the top electrode are in a range of 100-500 nm, and the thickness of the intermediate resistive layer is in a range of 30-50 nm.

6. A fabrication method of the resistive memory comprising a transparent flexible substrate, a memory unit with a MIM capacitor structure over the substrate, wherein a bottom electrode and a top electrode of the memory unit are transparent and flexible, and an intermediate resistive layer is a transparent film of poly(p-xylylene), comprising the steps of:
1) depositing a transparent flexible material on a base plate to form a transparent flexible film substrate;
2) forming a transparent flexible bottom electrode over the substrate;
3) depositing a polymer film of poly(p-xylylene) over the bottom electrode as an intermediate resistive layer;
4) forming a transparent flexible top electrode over the intermediate resistive layer;
5) peeling the transparent flexible film substrate from the base plate to obtain the transparent flexible resistive memory.

7. The fabrication method according to claim 6, wherein, the base sheet in the step 1) is a silicon wafer or a glass wafer.

8. The fabrication method according to claim 6, wherein, in the step 1), the substrate is formed by depositing poly(p-xylylene) over the base plate by using polymer CVD method with a deposition speed between 20 nm/min and 200 nm/min in a vacuum atmosphere, and in the step 3), the intermediate resistive layer is formed by depositing poly(p-xylylene) over the bottom electrode by using polymer CVD method with a deposition speed between 1 nm/min and 10 nm/min in a vacuum atmosphere.

9. The fabrication method according to claim 6, wherein, in the step 2) and step 4), an ITO film is sputtered, then is photolithographed to define the bottom electrode and the top electrode.

10. The fabrication method according to claim 6, wherein, lead-out vias of the bottom electrode are defined by performing a photolithography process and a reactive ion etching process to the polymer film of poly(p-xylylene) after step 3) and before step 4, and in step 4, the via are filled with material of the top electrode to lead the bottom electrode out.
